(19) United States
(12) Patent Application Publication
(10) Pub. No.: US 2025/0026648 A1
(43) Pub. Date: Jan. 23, 2025

(54) COMPOSITION CONTAINING NANOPARTICLES, NANORODS, AND NANOWIRES

(71) Applicant: NISSHIN SEIFUN GROUP INC., Tokyo (JP)

(72) Inventors: Yasunori TANAKA, Ishikawa (JP); Ryudai FURUKAWA, Ishikawa (JP); Yurina NAGASE, Ishikawa (JP); Shu WATANABE, Fujimino-city, Saitama (JP); Shiori SUEYASU, Fujimino-city, Saitama (JP); Keitaro NAKAMURA, Fujimino-city, Saitama (JP)

(21) Appl. No.: 18/714,877

(22) PCT Filed: Nov. 16, 2022
(86) PCT No.: PCT/JP2022/042517

§ 371 Date: May 30, 2024

(30) Foreign Application Priority Data
Nov. 30, 2021 (JP) 2021-194765

(51) Int. Cl. C01B 33/02; B01J 19/08; C01B 33/113; H01L 31/0224; H01L 33/40; H01M 4/02; H01M 4/36; H01M 4/38; H01M 4/48

(52) U.S. Cl. CPC C01B 33/02; C01B 33/113; H01M 4/364; H01M 4/386; H01M 4/48; B01J 19/08; B01J 2219/0898; C01P 2004/16; C01P 2004/64; C01P 2006/40; H01L 31/022425; H01L 33/40; H01M 2004/021

(57) ABSTRACT

Provided is a composition containing nanoparticles, nanorods, and nanowires that do not essentially require a carrier such as a substrate. The composition contains nanoparticles, nanorods, and nanowires, and the nanoparticles, the nanorods, and the nanowires are each formed of at least one of Si or SiO.

### TECHNICAL FIELD

The present invention relates to a composition containing nanoparticles, nanorods, and nanowires.

### BACKGROUND ART

At present, fine particles such as silicon fine particles, oxide fine particles, nitride fine particles and carbide fine particles are used in a wide variety of fields. Meanwhile, nanowires are attracting attention as a material that improves performance of semiconductor devices, sensors, solar cells, lithium ion batteries, or other devices. The above-mentioned fine particles and nanowires have been used in various applications.

For instance, Patent Literature 1 describes an electrode material for an electrochemical device, in which electrode material, a plurality of silicon nanowires containing silicon are disposed to a plurality of independent particles containing silicon, the silicon nanowires are entangled with each other to form a silicon nanowire network, and the independent particles and the silicon nanowire network occlude lithium.

The independent particles are joined to each other in the silicon nanowire network, and the independent particles and the silicon nanowires have diameters of about 0.5 to 10 μm and about 10 nm to 500 nm, respectively.

Patent Literature 2 describes a solar cell including a substrate, a first ++ type polycrystalline silicon layer provided on the substrate, a first type silicon nanowire layer containing a first type silicon nanowire that has grown from the first ++ type polycrystalline silicon layer, an intrinsic layer formed on the substrate having the first type silicon nanowire layer, and a second type doping layer formed on the intrinsic layer.

Patent Literature 2 also describes a method for forming silicon nanowires, the method including a first ++ type polycrystalline silicon layer forming step of forming a first ++ type polycrystalline silicon layer on a substrate, a metallic thin film layer forming step of forming a metallic thin film layer on the first ++ type polycrystalline silicon layer, a metallic nanoparticle forming step of forming metallic thin film layers on metallic nanoparticles, and a first type silicon nanowire growing step of growing first type silicon nanowires from the first ++ type polycrystalline silicon layer using the metallic nanoparticles as seeds.

### CITATION LIST

### Patent Literature

Patent Literature 1: JP 2008-269827 A
Patent Literature 2: JP 2010-192870 A

### SUMMARY OF INVENTION

### Technical Problems

In the silicon nanowire network of Patent Literature 1, the independent particles have a large diameter of about 0.5 to 10 μm. While silicon swells when being charged, silicon together with silicon nanowires is formed into a solid electrode so that silicon has room, whereby volume expansion of silicon can be absorbed. However, silicon particles having a large particle size require large room around each silicon particle, and it is difficult to perfectly avoid cracks. When the silicon nanowire network of Patent Literature 1 is used in an electrode material, sufficient performance cannot be exhibited. In addition, the method of producing an electrode material of Patent Literature 1 has no description of a method of producing independent particles having a small particle size.

Patent Literature 2 describes a first type silicon nanowire layer formed on a substrate but is silent as to nanoparticles. In addition, Patent Literature 2 does not describe a method of producing nanoparticles. Moreover, Patent Literature 2 essentially requires a carrier such as a substrate and does not produce nanowires alone. If nanowires alone are produced by scraping the nanowire layer off from the substrate, nanowires are crushed and cannot be independently collected.

As described above, at present, there is no mixture of nanosized fine particles (nanoparticles) and nanowires that do not essentially require a carrier such as a substrate.

The present invention aims at providing a composition containing nanoparticles, nanorods, and nanowires that do not essentially require a carrier such as a substrate.

### Solution to Problems

In order to attain the above-described object, an embodiment of the present invention provides a composition containing nanoparticles, nanorods, and nanowires, wherein the nanoparticles, the nanorods, and the nanowires are each formed of at least one of Si or SiO.

The nanoparticles preferably have a particle size of not more than 100 nm.

The nanoparticles preferably have a ratio β/α of less than 3, provided that a minor axis diameter is α, and a major axis diameter is β.

The nanorods preferably have a diameter of not less than 40 nm and not more than 80 nm.

The nanowires preferably have a diameter of not less than 1 nm and less than 40 nm.

### Advantageous Effects of Invention

The invention can provide a composition containing nanoparticles, nanorods, and nanowires that do not essentially require a carrier such as a substrate.

### BRIEF DESCRIPTION OF DRAWINGS

FIG. 1 is a schematic view showing an example of a composition production apparatus according to an embodiment of the invention.

FIG. 2 is a partial cross-sectional view schematically showing an example of a plasma torch of the composition production apparatus according to the embodiment of the invention.

FIG. 3 is a schematic view showing an example of a waveform of high frequency current of a power source section of a plasma generation section.

FIG. 4 is a schematic view showing an example of a waveform of high frequency current of the plasma generation section.

FIG. 5 is a graph showing an example of a waveform of high frequency current of a first coil, an example of a waveform of high frequency current of a second coil, and an example of a waveform of feedstock supply.

FIG. 6 is a graph showing calculation results of thermal equilibrium particle composition when argon gas is used.

FIG. 7 is a graph showing calculation results of thermal equilibrium particle composition when argon gas and hydrogen gas are used.

FIG. 8 is a graph showing diameter frequency distribution of a composition of Experimental Example 1.

FIG. 9 is a graph showing an XRD of the composition of Experimental Example 1.

FIG. 10 is a schematic view showing an SEM image of the composition of Experimental Example 1.

FIG. 11 is a schematic view showing an enlarged SEM image of the composition of Experimental Example 1.

### DESCRIPTION OF EMBODIMENTS

On the following pages, a composition of the invention is described in detail with reference to a preferred embodiment shown in the accompanying drawings.

It should be noted that the drawings described below are illustrative to explain the invention, and the invention is not construed to be limited to the drawings described below.

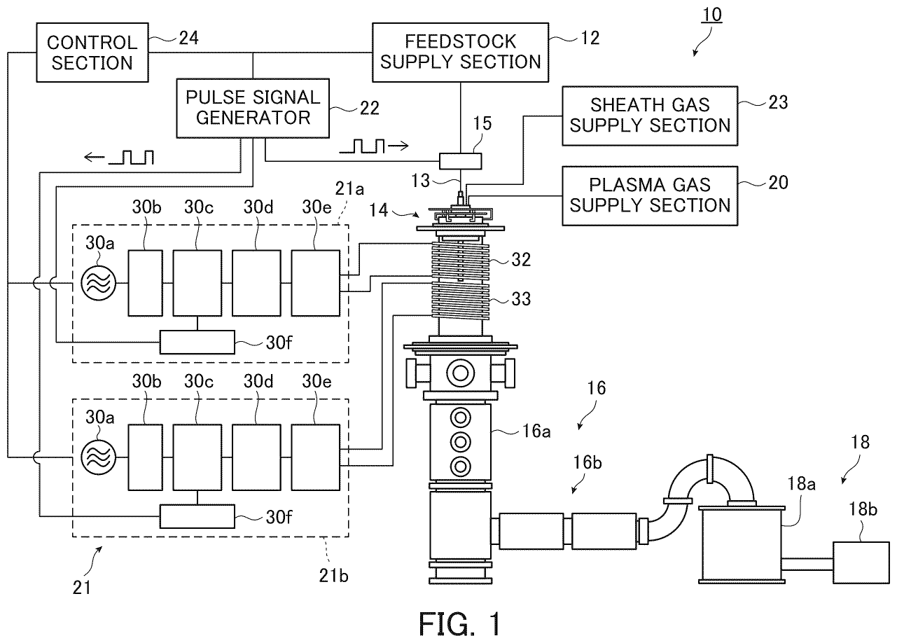

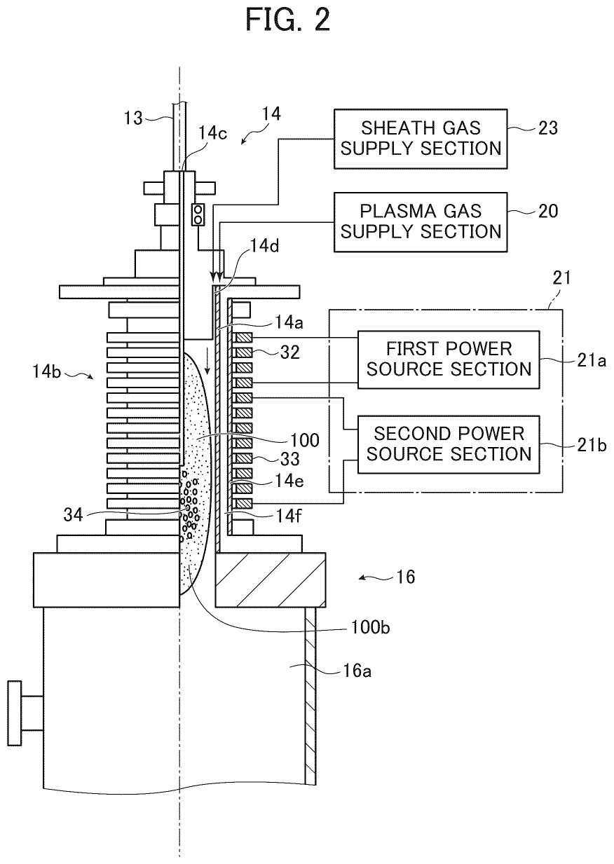

FIG. 1 is a schematic view showing an example of a composition production apparatus according to an embodiment of the invention, and FIG. 2 is a partial cross-sectional view schematically showing an example of a plasma torch of the composition production apparatus according to the embodiment of the invention.

A composition production apparatus 10 (hereinafter, referred to simply as “production apparatus 10”) shown in FIG. 1 produces a composition containing nanoparticles, nanorods, and nanowires by use of feedstock for composition production.

As the feedstock for the composition containing nanoparticles, nanorods, and nanowires, for instance, SiO (silicon monoxide) or SiOx (where 0<x<2, x≠1) is used.

The feedstock for the composition containing nanoparticles, nanorods, and nanowires takes a form of powder, for example, and the feedstock powder is supplied to the production apparatus 10 by use of carrier gas. Argon gas, helium gas, and mixed gas of argon gas and oxygen gas are usable as the carrier gas, for example.

### [Composition]

The composition contains nanoparticles, nanorods, and nanowires as described above, and nanoparticles, nanorods, and nanowires do not essentially require a carrier such as a substrate. The nanoparticles, nanorods, and nanowires are each formed of at least one of Si or SiO.

### <Nanoparticles>

The nanoparticles are nanosized fine particles and have a particle size of not more than 100 nm. The particle size of the nanoparticles is preferably 10 to 100 nm. The nanoparticles are preferably spherical but are not limited to a spherical shape. For instance, the nanoparticles are defined to have a ratio β/α of less than 3, provided that the minor axis diameter is α and the major axis diameter is β.

The particle size of the nanoparticles represents an average value of fine particle sizes obtained by acquiring plural SEM images of fine particles using a scanning electron microscope (SEM) and measuring particle sizes of 500 fine particles in total that are randomly extracted from three to five SEM images. The average value of particle sizes can be also obtained by analyzing three to five SEM images, randomly extracting 500 fine particles in total, and, while regarding the 500 fine particles as spheres, measuring diameters of regions equivalent to the spheres.

The nanoparticles include those having the ratio β/α of less than 3 as described above. Hence, also of non-spherical fine particles, the minor axis-equivalent length and the major axis-equivalent length are measured, and the ratio β/α is obtained.

The nanoparticles may carry on their surfaces or may be coated with a substance such as carbon aside from constituents of the nanoparticles.

### <Nanorods>

The nanorods are defined to have a diameter of not less than 40 nm and not more than 80 nm and a length of at least three times the diameter. The upper limit of the length of the nanorods is not particularly limited as long as the length is at least three times the diameter, and is, for example, subjected to production restriction or other restrictions. The nanorods are wire-shaped objects having a larger diameter than that of the nanowires.

The diameter of the nanorods represents an average value of nanorod diameters obtained by acquiring multiple SEM images of nanorods using an SEM and measuring diameters of 500 nanorods in total that are randomly extracted from three to five SEM images. The average value of diameters can be also obtained by analyzing three to five SEM images and measuring diameters of regions equivalent to diameters of 500 nanorods in total that are randomly extracted.

The length of the nanorods represents an average value of nanorod lengths obtained by acquiring multiple images of nanorods using an SEM and measuring lengths of 500 nanorods in total that are randomly extracted from three to five SEM images. The average value of lengths can be also obtained by analyzing three to five SEM images and measuring lengths of regions equivalent to lengths of 500 nanorods in total that are randomly extracted.

The nanorods may carry on their surfaces or may be coated with a substance such as carbon aside from constituents of the nanorods, as with the nanoparticles described above.

### <Nanowires>

The nanowires are defined to have a diameter of less than 40 nm and a length of at least three times the diameter. The upper limit of the length of the nanowires is not particularly limited as long as the length is at least three times the diameter, and is, for example, subjected to production restriction or other restrictions. The nanowires are wire-shaped objects having a thinner diameter than that of the nanorods.

The diameter of the nanowires represents an average value of nanowire diameters obtained by acquiring multiple images of nanowires using an SEM and measuring diameters of 500 nanowires in total that are randomly extracted from three to five SEM images. The average value of diameters can be also obtained by analyzing three to five SEM images and measuring diameters of regions equivalent to diameters of 500 nanowires in total that are randomly extracted.

The length of the nanowires represents an average value of nanowire lengths obtained by acquiring multiple images of nanowires using an SEM and measuring lengths of 500 nanowires in total that are randomly extracted from three to five SEM images. The average value of lengths can be also obtained by analyzing three to five SEM images and measuring lengths of regions equivalent to lengths of 500 nanowires in total that are randomly selected.

The nanowires may carry on their surfaces or may be coated with a substance such as carbon aside from constituents of the nanowires, as with the nanoparticles described above.

### (Composition Production Apparatus)

Hereinafter, the production apparatus 10 shown in FIG. 1 is described more specifically.

The production apparatus 10 shown in FIG. 1 includes a feedstock supply section 12, a plasma torch 14, a chamber 16, a collection section 18, a plasma gas supply section 20, a plasma generation section 21, a pulse signal generator 22, a sheath gas supply section 23, and a control section 24. The control section 24 is configured to control the respective sections of the production apparatus 10.

The feedstock supply section 12 is connected to the plasma torch 14 through a hollow supply tube 13.

Between the feedstock supply section 12 and the plasma torch 14, disposed is an intermittent supply section 15 as described later. The feedstock supply section 12 is connected to the intermittent supply section 15 that is disposed above the plasma torch 14 through the supply tube 13.

The chamber 16 is disposed below the plasma torch 14, and the collection section 18 is disposed at the chamber 16. The plasma generation section 21 is connected to the plasma torch 14, and a thermal plasma flame 100 (see FIG. 2) is generated in the plasma torch 14 by means of the plasma generation section 21 as described later.

The feedstock supply section 12 is configured to supply feedstock for the composition into the thermal plasma flame 100 generated in the plasma torch 14. The feedstock supply section 12 is not particularly limited as long as it can supply feedstock for the composition into the thermal plasma flame 100.

In a case where SiO or SiOx powder is used as the feedstock for the composition (hereinafter, the feedstock for the composition may be simply referred to as “feedstock”), the feedstock needs to be dispersed in a particulate form when supplied into the thermal plasma flame 100 in the plasma torch 14. Therefore, the feedstock is, for instance, dispersed in carrier gas so that the feedstock in a particulate form is supplied. In this case, the feedstock supply section 12 supplies the powdery feedstock in a particulate state into the thermal plasma flame 100 in the plasma torch 14 whilst maintaining the feedstock to be in a dispersed state, for example. For the feedstock supply section 12 having such a function, usable examples include devices disclosed in JP 3217415 B and JP 2007-138287 A.

For example, the feedstock supply section 12 includes a storage tank (not shown) storing feedstock powder, a screw feeder (not shown) transporting the feedstock powder in a fixed amount, a dispersion section (not shown) dispersing the feedstock powder transported by the screw feeder into a particulate form before the feedstock powder is finally sprayed, and a carrier gas supply source (not shown).

Together with carrier gas to which push-out pressure is applied from the carrier gas supply source, the feedstock powder is supplied into the thermal plasma flame 100 in the plasma torch 14 through the supply tube 13.

The configuration of the feedstock supply section 12 is not particularly limited as long as the feedstock supply section 12 can prevent the feedstock powder from agglomerating and spray the feedstock powder into the plasma torch 14 with the feedstock powder being dispersed in a particulate form and the dispersed state being maintained. As the carrier gas, for example, not only argon gas (Ar gas) but helium gas and mixed gas of argon gas and oxygen gas are usable.

As described above, examples of the feedstock for the composition include SiO or SiOx, and, for example, SiO or SiOx powder is used. SiO or SiOx powder is appropriately designed to have an average particle size which allows easy evaporation of the powder in a thermal plasma flame. The average particle size of SiO or SiOx powder has, for example, d₅₀ of not more than 100 μm, preferably not more than 10 μm, and more preferably not more than 5 μm.

The average particle size d₅₀ of SiO or SiOx powder represents a median in a particle size frequency distribution.

The plasma torch 14 is configured to allow the thermal plasma flame 100 to be generated therein and, by use of the thermal plasma flame 100, evaporate the feedstock supplied by the feedstock supply section 12 to transform the feedstock into a mixture 34 in a gas phase state.

As shown in FIG. 2, the plasma torch 14 includes a quartz tube 14a and a high frequency oscillation coil 14b provided around the outer surface of the quartz tube 14a to surround the periphery of the plasma torch 14. The center portion of the top of the plasma torch 14 is provided with a supply port 14c into which the supply tube 13 is inserted, and a plasma gas supply port 14d is formed in the peripheral portion of the supply port 14c (on the same circumference).

For instance, the powdery feedstock and the carrier gas such as argon gas are supplied into the plasma torch 14 through the supply tube 13.

The plasma gas supply port 14d is connected to the plasma gas supply section 20 via, for example, piping which is not shown. The plasma gas supply section 20 is configured to supply plasma gas into the plasma torch 14 through the plasma gas supply port 14d. For the plasma gas, gases such as argon gas and hydrogen gas are used alone or in combination as appropriate, for instance.

A sheath gas supply section 23 supplying sheath gas into the plasma torch 14 may be provided in addition to the plasma gas supply section 20. For the sheath gas, gases such as argon gas and hydrogen gas can be used alone or in combination as appropriate, for instance. The plasma gas supply section 20 and the sheath gas supply section 23 basically have the same configuration, and only gas type is different between them.

Hydrogen gas used for the plasma gas or the sheath gas has a large specific enthalpy and a large thermal conductivity. By mixing hydrogen gas with the plasma gas or the sheath gas, an improvement in evaporation efficiency of the feedstock powder is expected, and an effect of reducing oxygen from evaporated vapor of feedstock is obtained.

The outside of the quartz tube 14a of the plasma torch 14 is surrounded by a concentrically formed quartz tube 14e, and cooling water 14f is circulated between the quartz tubes 14a and 14e to cool the quartz tube 14a with the water, thereby preventing the quartz tube 14a from having an excessively high temperature due to the thermal plasma flame 100 generated in the plasma torch 14.

The intermittent supply section 15 is disposed between the feedstock supply section 12 and the plasma torch 14 and is connected to the supply tube 13. The intermittent supply section 15 is also connected to the pulse signal generator 22.

For the intermittent supply section 15, for instance, a solenoid valve (electromagnetic valve) is used. The intermittent supply section 15 time-modulates an amount of supply of the feedstock. The intermittent supply section 15 controls opening and closing of the solenoid valve in accordance with pulse signals output from the pulse signal generator 22.

It takes time after the solenoid valve is opened until the feedstock is actually transported and the amount of supply of the feedstock into the thermal plasma flame 100 increases, and therefore, the solenoid valve and the like need to be controlled taking the time required for the transportation into account.

A ball valve may be used instead of the solenoid valve for the intermittent supply section 15. Also in this case, the opening and closing of the ball valve is controlled in accordance with pulse signals output from the pulse signal generator 22. As with the solenoid valve, the feedstock is actually transported after the ball valve is opened, and therefore, the ball valve needs to be controlled taking the time required for the transportation into account.

The plasma generation section 21 is provided to generate the thermal plasma flame 100 in the plasma torch 14 as described above. The plasma generation section 21 includes a first coil 32 surrounding the periphery of the plasma torch 14, a second coil 33 surrounding the periphery of the plasma torch 14, a first power source section 21a supplying high frequency current to the first coil 32, and a second power source section 21b supplying high frequency current to the second coil 33. The high frequency current supplied to the first coil 32 is also called first coil current, and the high frequency current supplied to the second coil 33 is also called second coil current.

The first coil 32 and the second coil 33 are arranged side by side in the longitudinal direction of the plasma torch 14, and the second coil 33 is disposed under the first coil 32.

The first power source section 21a and the second power source section 21b are both high frequency power sources and are independent of each other. It is preferable that the frequency of high frequency current of the first power source section 21a and the frequency of high frequency current of the second power source section 21b be different from each other in order to reduce magnetic coupling between the first coil 32 and the second coil 33. This configuration can suppress the influence of the power source sections on each other.

The first coil 32 and the second coil 33 constitute the high frequency oscillation coil 14b. The numbers of turns of the first coil 32 and the second coil 33 are not particularly limited and suitably determined depending on the configuration of the production apparatus 10. Materials of the first coil 32 and the second coil 33 are also not particularly limited and suitably determined depending on the configuration of the production apparatus 10.

With the use of the two coils and the two independent power source sections in the plasma generation section 21, a series structure of induction thermal plasma can be built. The provision of the series structure of induction thermal plasma makes it possible to generate a high-temperature field that is long in the axial direction of the plasma torch 14. When the long high-temperature field as above is used, it is possible to completely evaporate a high melting point material. A thermal plasma flame that is periodically switched between a high temperature state and a low temperature state having a lower temperature than that in the high temperature state at predetermined time intervals, i.e., that is time-modulated in terms of the temperature state, is called a modulated induction thermal plasma flame.

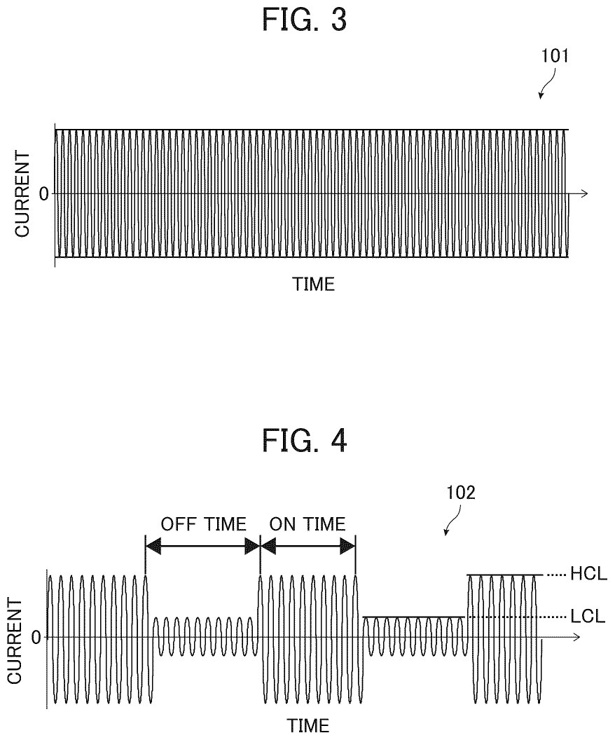

For instance, the plasma generation section 21 supplies at least one of the first coil 32 or the second coil 33 with unmodulated high frequency current that is not subjected to amplitude modulation (see FIG. 3).

The plasma generation section 21 also supplies at least one of the first coil 31 or the second coil 33 with amplitude-modulated high frequency current (see FIG. 4).

For instance, when unmodulated high frequency current (see FIG. 3) is supplied to the first coil 32 and amplitude-modulated high frequency current (see FIG. 4) is supplied to the second coil 33, the thermal plasma flame 100 is generated in the plasma torch 14. The temperature of the thermal plasma flame 100 can be changed by use of the amplitude-modulated high frequency current supplied to the second coil 33, thereby controlling the temperature inside the plasma torch 14. The temperature state of the thermal plasma flame 100 is time-modulated, so that the temperature state of the thermal plasma flame 100 is periodically switched between the high temperature state and the low temperature state having a lower temperature than that in the high temperature state.

It should be noted that by supplying unmodulated high frequency current to the first coil 32 to generate the thermal plasma flame 100, it is possible to stabilize the thermal plasma flame 100, and destabilization of the thermal plasma flame 100 can be suppressed even when high frequency current supplied to the second coil 33 is modulated. This configuration makes it possible to suppress a decrease in the temperature of the thermal plasma flame 100 even when, for instance, a large amount of feedstock is supplied to the thermal plasma flame 100.

In the plasma generation section 21, the high frequency current supplied to the first coil 32 and the second coil 33 can be either unmodulated high frequency current that is not subjected to amplitude modulation (see FIG. 3) or amplitude-modulated high frequency current (see FIG. 4), and the combination thereof is not particularly limited.

FIG. 3 is a schematic view showing an example of a waveform of high frequency current of the power source section of the plasma generation section, and FIG. 4 is a schematic view showing an example of a waveform of high frequency current of the plasma generation section.

FIG. 3 shows a waveform 101 of the unmodulated high frequency current that is not subjected to amplitude modulation described above, where the amplitude is constant and does not change. FIG. 4 shows a waveform 102 of the amplitude-modulated high frequency current described above, where the amplitude is periodically modulated over time. FIG. 4 shows square wave amplitude modulation. The amplitude modulation is not limited to the square wave amplitude modulation shown in FIG. 4, and needless to say, use may be made of a waveform formed of a repetitive wave including a curved line having a triangle wave, a sawtooth wave, a reverse sawtooth wave, a sine wave or the like.

In the amplitude-modulated high frequency current, the high value of the current amplitude is defined as a higher current level (HCL), the low value of the current amplitude is defined as a lower current level (LCL), and the time with HCL and the time with LCL in one modulation cycle are respectively defined as the ON time and the OFF time. Further, the percentage of the ON time in one cycle: (ON time/(ON time+OFF time)×100(%)) is defined as a duty factor (DF). The ratio (LCL/HCL×100(%)) in the amplitude is defined as a current modulation ratio (SCL). The current modulation ratio (SCL) represents the degree of modulation of current amplitude, where 100% SCL represents an unmodulated state and 0% SCL represents that the current amplitude is most largely modulated. At 0% SCL, the current value of high frequency current is 0 ampere (A) during the OFF time, i.e., in a region where the current amplitude of high frequency current is low, which will be described later. The amplitude modulation is not particularly limited as long as the SCL value is not less than 0% SCL and less than 100% SCL, and 0% SCL is most preferable because a value closer to 0% SCL refers to a higher degree of modulation, i.e., larger amplitude modulation.

The ON time (see FIG. 4) corresponds to a region where the current amplitude of high frequency current is high, and the OFF time (see FIG. 4) corresponds to a region where the current amplitude of high frequency current is low. The ON time, the OFF time, and the one cycle described above are each preferably on the order of microseconds to several seconds.

The ambient pressure inside the plasma torch 14 is suitably determined depending on production conditions of fine particles and is, for example, not higher than the atmospheric pressure. The atmosphere with a pressure of not higher than the atmospheric pressure is not particularly limited, and for example, the pressure may range from 5 Torr (666.5 Pa) to 750 Torr (99.975 kPa).

As to the chamber 16, as shown in FIG. 1, from the side closer to the plasma torch 14, an upstream chamber 16a is attached to the plasma torch 14 to be concentric therewith. A downstream chamber 16b is provided perpendicularly to the upstream chamber 16a, and on a further downstream side, there is provided the collection section 18 including a desired filter 18a for collecting fine particles. In the production apparatus 10, a fine particle collection site is for example the filter 18a.

The chamber 16 serves as a cooling tank, and the composition (not shown) is generated in the chamber 16.

The collection section 18 includes a collection chamber having the filter 18a, and a vacuum pump 18b connected through a pipe provided at a lower portion of the collection chamber. The fine particles transported from the chamber 16 are sucked by the vacuum pump 18b to be introduced into the collection chamber, and those fine particles remaining on the surface of the filter 18a are collected.

The first power source section 21a and the second power source section 21b of the plasma generation section 21 are specifically described.

Since the first power source section 21a and the second power source section 21b have the same configuration, the first power source section 21a is described while detailed description of the second power source section 21b is omitted.

As shown in FIG. 1, the first power source section 21a and the second power source section 21b each include an RF power source 30a, a rectifier circuit 30b, a DC-DC converter 30c, a high frequency inverter 30d, an impedance matching circuit 30e, and a pulse width modulation (PWM) controller 30f.

The RF power source 30a serves as an input power source and makes use of, for example, a three-phase alternating current power source.

The rectifier circuit 30b performs alternating current-direct current conversion and makes use of, for example, a three-phase full-wave rectifier circuit.

The DC-DC converter 30c changes the output voltage value and makes use of, for example, an insulated gate bipolar transistor (IGBT).

The high frequency inverter 30d converts a direct current into an alternating current, has the function of modulating the amplitude of electric current, and can amplitude-modulate a coil current. The high frequency inverter 30d makes use of, for example, a metal oxide semiconductor field effect transistor (MOSFET) inverter.

The output side of the high frequency inverter 30d is connected with the impedance matching circuit 30e. The impedance matching circuit 30e is constituted of, for example, a series resonant circuit composed of a capacitor and a resonant coil and carries out impedance matching such that a resonance frequency of load impedance including plasma load falls within a drive frequency range of the high frequency inverter 30d.

The PWM controller 30f modulates current amplitude in accordance with a modulation signal based on the pulse control signal generated by the pulse signal generator 22 and includes, for example, an FET gate signal circuit (not shown). The PWM controller 30f is connected with the DC-DC converter 30c. The PWM controller 30f is also connected with the pulse signal generator 22.

The pulse signal generator 22 generates a pulse control signal for adding square wave modulation to the amplitude of the coil current used to maintain high frequency modulated induction thermal plasma. The PWM controller 30f obtains, from the pulse control signal, a modulation signal for modulating the current amplitude.

The PWM controller 30f supplies a modulation signal based on a pulse control signal generated by the pulse signal generator 22 to the DC-DC converter 30c and modulates the current amplitude by, for example, switching the IGBT. In this manner, in the first power source section 21a, the coil current can be amplitude-modulated by use of the modulation signal based on the pulse control signal generated by the pulse signal generator 22 such that the amplitude relatively increases or decreases, and for example, the coil current can be pulse-modulated as shown in FIG. 4. The pulse modulation of the coil current allows the thermal plasma flame 100 to be periodically switched between the high temperature state and the low temperature state having a lower temperature than the high temperature state at predetermined time intervals. In the plasma generation section 21, a high frequency current may be simply supplied to the high frequency oscillation coil 14b, thereby generating a thermal plasma flame having a constant temperature state.

When the feedstock is intermittently supplied, the feedstock is supplied in synchronization with the high temperature state of the thermal plasma flame 100 so that the feedstock is completely evaporated in the high temperature state to have the mixture 34 in a gas phase state (see FIG. 2).

The first power source section 21a makes use of, for example, a three-phase alternating current power source as the input power source, and after the alternating current-direct current conversion is performed through a three-phase full-wave rectifier circuit, the output value thereof is changed through the DC-DC converter 30c. The high frequency inverter 30d then converts a direct current that has been obtained by the rectifier circuit 30b and that has gone through the DC-DC converter 30c into an alternating current. By supplying the modulation signal based on the pulse control signal to the DC-DC converter 30c and switching the IGBT as described above, an inverter output, i.e., a coil current is amplitude-modulated (AM modulated). The impedance matching circuit 30e carries out impedance matching such that a resonance frequency of load impedance including plasma load falls within a drive frequency range of the high frequency inverter 30d as described above.

In addition, the second power source section 21b has the same configuration as that of the first power source section 21a and can pulse modulate the coil current as with the first power source section 21a. The first power source section 21a and the second power source section 21b can have the coil current unmodulated. In this case, for example, the pulse signal generator 22 does not input a pulse control signal.

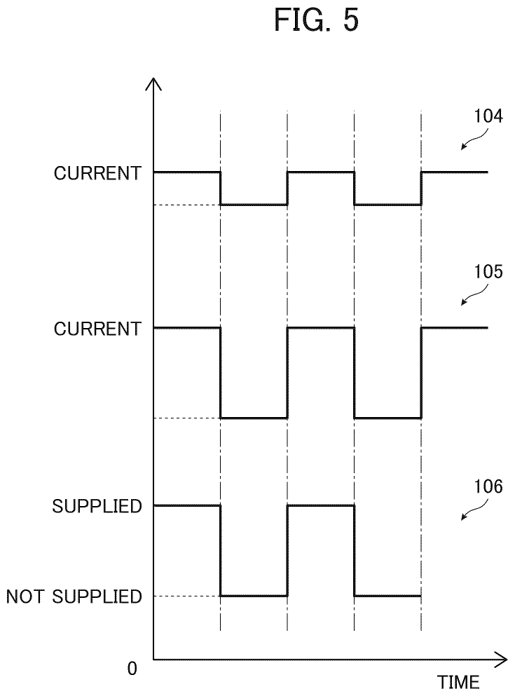

FIG. 5 is a graph showing an example of a waveform of high frequency current of the first coil, an example of a waveform of high frequency current of the second coil, and an example of a waveform of the feedstock supply. In FIG. 5, numeral 104 shows a waveform of high frequency current of the first coil, numeral 105 shows a waveform of high frequency current of the second coil, and numeral 106 shows a waveform of the feedstock supply.

In FIG. 5, the current value of high frequency current of the first coil and the current value of high frequency current of the second coil change in synchronization with each other. Hence, when the high frequency current of the first coil has a high current value, the high frequency current of the second coil also has a high current value, and when the high frequency current of the first coil has a low current value, the high frequency current of the second coil also has a low current value. When the high frequency currents of the first coil and of the second coil have high current values, the thermal plasma flame 100 is in the high temperature state, and when the high frequency currents of the first coil and of the second coil have low current values, the thermal plasma flame 100 is in the low temperature state.

The feedstock is supplied when the thermal plasma flame 100 is in the high temperature state and is not supplied when the thermal plasma flame 100 is in the low temperature state. The feedstock can be efficiently evaporated, and evaporated vapor can be cooled in this manner. By increasing the modulation of high frequency current of the second coil, the evaporated vapor can be better cooled.

### (Composition Production Method)

Hereinafter, a composition production method using the foregoing production apparatus 10 is described. The composition production method is not limited to a method using the production apparatus 10.

First, as the feedstock powder for the composition, for instance, SiO or SiOx powder having d₅₀ of 5 μm is prepared.

Argon gas is used as the plasma gas, for example, and a high frequency voltage is applied to the high frequency oscillation coil 14b (see FIG. 2) to generate the thermal plasma flame 100 in the plasma torch 14.

Next, the SiO or SiOx powder is transported with, for example, argon gas used as the carrier gas and supplied into the thermal plasma flame 100 in the plasma torch 14 through the supply tube 13. At that time, hydrogen gas is supplied as the sheath gas.

The thermal plasma flame is generated in the plasma torch 14, and at this time, the first coil and the second coil both do not have the coil current modulated. In other words, the temperature state of the thermal plasma flame 100 is not modulated. In this process, the supply amount of the feedstock does not change, and the feedstock is supplied in a constant amount.

The supplied SiO or SiOx powder is evaporated in the thermal plasma flame 100 and becomes the mixture 34 in a gas phase state (see FIG. 2). In the chamber 16, nanoparticles, nanorods, and nanowires that are formed of at least one of Si or SiO are generated, and the composition containing nanoparticles, nanorods, and nanowires is obtained. In this regard, it is assumed that since hydrogen gas is used as the sheath gas, SiO or SiOx evaporation and cooling processes are altered, and products having different shapes, i.e., the nanoparticles, the nanorods, and the nanowires are obtained.

The nanoparticles, the nanorods, and the nanowires obtained in the chamber 16 do not essentially require a carrier such as a substrate and are collected on the filter 18a of the collection section 18 owing to negative pressure (suction force) applied from the collection section 18 by the vacuum pump 18b, as described above. The nanoparticles, the nanorods, and the nanowires are not in the form of being fixed onto a substrate but are each separately present.

The mechanism by which nanoparticles, nanorods, and nanowires are generated is described below. In particular, the mechanism of nucleus generation of an SiO-based material was studied in terms of thermodynamics.

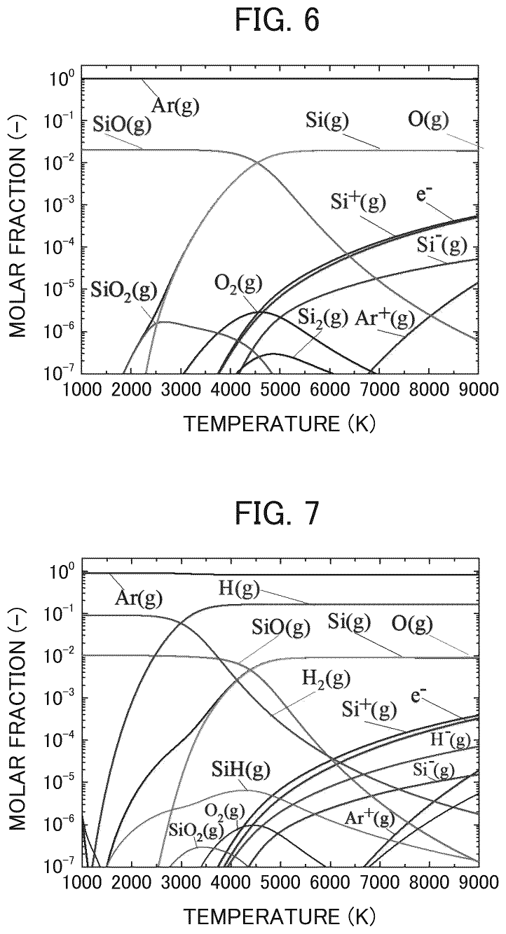

FIG. 6 is a graph showing calculation results of a thermal equilibrium particle composition when argon gas is used, and FIG. 7 is a graph showing calculation results of a thermal equilibrium particle composition when argon gas and hydrogen gas are used.

FIG. 6 shows calculation results of the particle composition having a compositional ratio of 98 mol % of Ar and 2 mol % of SiO at pressure of 300 torr (≅40 kPa). This compositional ratio represents a simulated gas mixing ratio at the time of nano material generation when an SiO material is introduced into inductively coupled thermal plasma (ICTP) of argon gas.

FIG. 6 teaches that when an SiO material is introduced into thermal plasma at temperature exceeding 10,000K, the Si—O bond is broken, thereby generating Si atoms and O atoms. From this state, as the temperature of the thermal plasma is decreased to 5,000K or lower, gas phase SiO is mainly generated from Si atoms and O atoms while gas phase Si is also present. Presumably, nuclei are generated from these phases, whereby Si nanoparticles and SiO nanoparticles are generated.

In the meantime, FIG. 7 shows calculation results of a thermal equilibrium particle composition of Ar—H—O—Si-based vapor, i.e., calculation results of the particle composition when the compositional ratio is 90 mol % of Ar, 1 mol % of SiO, and 9 mol % of H₂ at pressure of 300 torr (≅40 kPa). This compositional ratio represents a simulated gas mixing ratio at the time of nano material generation when an SiO material is introduced into inductively coupled thermal plasma (ICTP) of argon gas and hydrogen gas.

FIG. 7 teaches that when the temperature of the thermal plasma is decreased from 10,000K to 5,000K, gas phase SiO is generated while gas phase Si is also present. It can be seen that even when the temperature of the thermal plasma is further decreased to 3,000K or lower, more gas phase Si remains together with the gas phase SiO. In addition, since it is known that a temperature gradient becomes large under the thermal plasma condition where hydrogen gas is mixed, the vapor temperature is expected to more rapidly decrease. Therefore, it is expected that more homogeneous nucleation of Si occurs when an SiO material is introduced into inductively coupled thermal plasma (ICTP) of argon gas and hydrogen gas, compared to a case where an SiO material is introduced into inductively coupled thermal plasma (ICTP) of argon gas. Then, presumably, growth of SiO in a particular direction is promoted due to the larger amount of generated Si nuclei and the change in temperature gradient, whereby nanoparticles, nanorods, and nanowires are generated.

### (Applications)

Applications of the composition containing the nanoparticles, the nanorods, and the nanowires include, for example, a negative electrode material of a lithium ion battery, a flexible device such as a sensor which functions as an electronic skin, a solar cell, a data storage device, and a light-emitting diode.

The present invention is basically configured as above. While the mixture production apparatus and the mixture production method according to the invention are described above in detail, the invention is by no means limited to the foregoing embodiments and it should be understood that various improvements and modifications are possible without departing from the scope and spirit of the invention.

### EXAMPLES

The composition of the invention is more specifically described below.

In the present example, production of the composition containing the nanoparticles, the nanorods, and the nanowires was attempted (Experimental Example 1). The production apparatus 10 shown in FIG. 1 was used for the composition containing the nanoparticles, the nanorods, and the nanowires. Shown below are the production conditions.

As a production condition, SiO powder having d₅₀ of 5 μm was used. The average particle size of the SiO powder is a value measured with a particle size distribution meter. It should be noted that d₅₀ refers to a median of the particle size distribution of SiO powder.

In supplying the feedstock, Ar gas was used as the carrier gas, and the feedstock was supplied at a rate of 1.43 g/minute together with the carrier gas. The flow rate of the carrier gas was 4 L/minute (as being converted to standard conditions).

Ar gas and hydrogen gas were used as the sheath gas, the flow rate of Ar gas was 90 L/minute (as being converted to standard conditions), and the flow rate of H₂ gas was 1.5 slpm (=1.5 L/minute (as being converted to standard conditions)).

The average input power to the first coil was constant at 15 kW, and the frequency was 400 kHz. The average input power to the second coil was 10 kW, and the frequency was 200 kHz.

The first coil and the second coil each had eight turns. The pressure inside the chamber was set to 300 torr (≅40 kPa).

The foregoing sheath gas serves as the plasma gas. The plasma was not modulated, and no quenching gas was used.

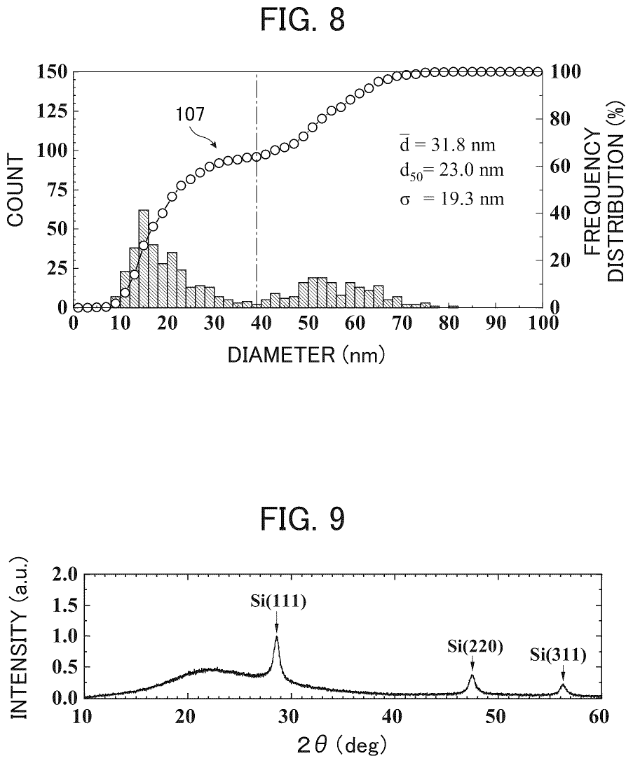

In Experimental Example 1, four SEM images were acquired, 500 wire-shaped objects in total were randomly extracted from the four SEM images, and the diameter of a region equivalent to each of the 500 wire-shaped objects was measured. As a result, the diameter frequency distribution shown in FIG. 8 was obtained. FIG. 8 is a graph showing the diameter frequency distribution of the composition of Experimental Example 1. The curve 107 shown in FIG. 8 shows the number of counts of wire-shaped objects.

In Experimental Example 1, wire-shaped objects having a wide variety of diameters were generated.

As shown in FIG. 8, the average diameter d was 31.8 nm, d₅₀ was 23.0 nm, and the standard deviation σ was 19.3 nm in Experimental Example 1. The d₅₀ represents a value relevant to diameter. The foregoing d₅₀ is a median of the diameter frequency distribution.

FIG. 8 teaches that wire-shaped objects having different diameters were generated in Experimental Example 1.

In Experimental Example 1, the crystal structure analysis was performed using X-ray diffractometry (XRD). The result is shown in FIG. 9. FIG. 9 is a graph showing the XRD of the composition of Experimental Example 1.

The XRD spectrum shown in FIG. 9 was normalized, having the peak value of Si(111) as 1. In Experimental Example 1, as evidenced by Si crystal peaks including the Si(111) peak observed, Si crystals were locally generated.

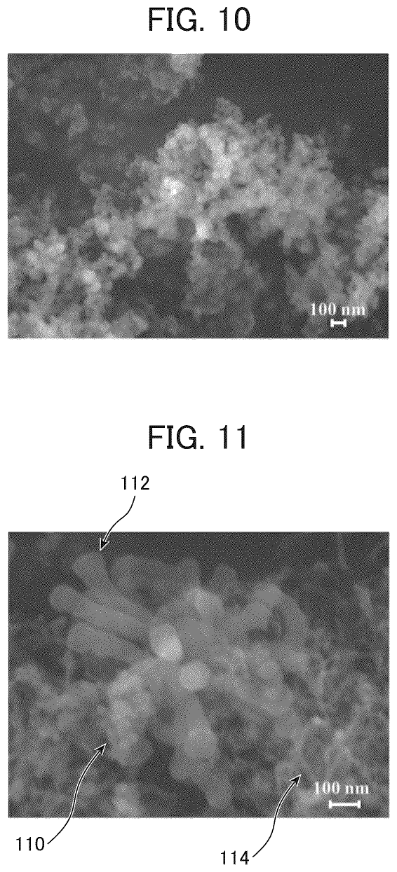

It is confirmed from the SEM images shown in FIGS. 10 and 11 that the composition in which the nanoparticles 110 (see FIG. 11), the nanorods 112 (see FIG. 11), and the nanowires 114 (see FIG. 11) were mixed was obtained. It should be noted that FIG. 10 is a schematic view showing the SEM image of the composition of Experimental Example 1, and FIG. 11 is a schematic view showing an enlarged SEM image of the composition of Experimental Example 1.

Particulate objects, i.e., nanoparticles, and wire-shaped nanowires having a diameter of several nanometers were generated, and at the same time, wire-shaped nanorods having a diameter of larger than 40 nm were generated. The composition containing the nanoparticles, the nanorods, and the nanowires was obtained as above.

### REFERENCE SIGNS LIST

10 fine particle production apparatus (production apparatus)
12 feedstock supply section
13 supply tube
14 plasma torch
14a quartz tube
14b high frequency oscillation coil
14c supply port
14d plasma gas supply port
14e quartz tube
14f cooling water
15 intermittent supply section
16 chamber
16a upstream chamber
16b downstream chamber
18 collection section
18a filter
18b vacuum pump
20 plasma gas supply section
21 plasma generation section
21a first power source section
21b second power source section
22 pulse signal generator
23 sheath gas supply section
24 control section
30a RF power source
30b rectifier circuit
30c DC-DC converter
30d high frequency inverter
30e impedance matching circuit
30f PWM controller
32 first coil
33 second coil
34 mixture
100 thermal plasma flame
101 waveform of unmodulated high frequency current
102 waveform of amplitude-modulated high frequency current
104 waveform of high frequency current of first coil
105 waveform of high frequency current of second coil
106 waveform of feedstock supply
107 curve
110 nanoparticle
112 nanorod
114 nanowire

1. A composition containing nanoparticles, nanorods, and nanowires,
wherein the nanoparticles, the nanorods, and the nanowires are each formed of at least one of Si or SiO.

2. The composition according to claim 1, wherein the nanoparticles have a particle size of not more than 100 nm.

3. The composition according to claim 2, wherein the nanoparticles have a ratio β/α of less than 3, provided that a minor axis diameter is α, and a major axis diameter is β.

4. The composition according to claim 1, wherein the nanorods have a diameter of not less than 40 nm and not more than 80 nm.

5. The composition according to claim 1, wherein the nanowires have a diameter of not less than 1 nm and less than 40 nm.

6. The composition according to claim 2, wherein the nanorods have a diameter of not less than 40 nm and not more than 80 nm.

7. The composition according to claim 3, wherein the nanorods have a diameter of not less than 40 nm and not more than 80 nm.

8. The composition according to claim 2, wherein the nanowires have a diameter of not less than 1 nm and less than 40 nm.

9. The composition according to claim 3, wherein the nanowires have a diameter of not less than 1 nm and less than 40 nm.

10. The composition according to claim 4, wherein the nanowires have a diameter of not less than 1 nm and less than 40 nm.
